(19) United States
(12) Patent Application Publication
(10) Pub. No.: US 2021/0332469 A1
(43) Pub. Date: Oct. 28, 2021

(54) METHOD FOR MANUFACTURING TWO-DIMENSIONAL MATERIAL

(71) Applicant: NATIONAL CHENG KUNG UNIVERSITY, TAINAN CITY (TW)

(72) Inventor: Jung-Chun HUANG, Tainan City (TW)

(21) Appl. No.: 16/910,082

(22) Filed: Jun. 24, 2020

(30) Foreign Application Priority Data
Apr. 23, 2020 (TW) 109113679

(51) Int. Cl. C23C 14/00; C23C 14/22; C23C 14/34

(52) U.S. Cl. CPC C23C 14/0047; C23C 14/3442; C23C 14/221

(57) ABSTRACT

A method for manufacturing a two-dimensional material is described. In this method, an energy beam sputtering process is performed by using a target to form a transition metal film on a substrate. When the energy beam sputtering process is performed, a potential difference between the target and the substrate is 0, such that no electric field is generated between the target and the substrate. A synthesis reaction is performed on the transition metal film within a tube furnace to synthesize a two-dimensional material layer from the transition metal film and chalcogen.

### RELATED APPLICATIONS

This application claims priority to Taiwan Application Serial Number 109113679, filed Apr. 23, 2020, which is herein incorporated by reference.

### BACKGROUND

### Field of Invention

The present disclosure relates to a technique for manufacturing a two-dimensional material. More particularly, the present disclosure relates to a method for manufacturing a large-area and high-quality two-dimensional material.

### Description of Related Art

Two-dimensional materials mainly include materials having layered structures, such as graphene, boron nitride, or transition metal dichalcogenide. The transition metal dichalcogenide may be represented by a chemical formula MX₂, in which M in the chemical formula may be Mo, W, Ta, Pt, V, Nb, etc., and X may be S, Se, and Te.

When the two dimensional materials are decreased to be single-atom thick or several-atom thick, they usually may generate new performances. Because single-layered graphene keeps a metallic state, and an energy gap of boron nitride is too large, the two kinds of the two-dimensional materials lack a semiconductor characteristic required for manufacturing semiconductor devices such as transistors. The transition metal dichalcogenide presents a semiconductor property and has various kinds, such that the transition metal dichalcogenide can be applied to manufacture the semiconductor devices such as transistors. For example, molybdenium disulfide (MoS₂) is n-type semiconductor, tungsten telluride (WTe₂) is p-type semiconductor, and platinum disulphide (PtS₂) and platinum diselenide (PtSe₂) have very high electron mobility. In addition, vanadium disulfide (VS₂) and vanadium diselenide (VSe₂) are magnetic, and niobium diselenide (NbSe₂) has a superconductor property. The transition metal dichalcogenide series materials have various physical properties, and structures of these materials are similar and can be stacked with each other as bricks, such that they are suitable to be applied to manufacture various electronic devices.

Currently, there are several techniques for manufacturing the transition metal dichalcogenide series materials. One technique uses a physical vapor deposition (PVD) method. In the physical vapor deposition technique, transition metal is firstly deposited on a substrate by a direct current (DC) or radio frequency (RF) magnetron sputtering method, and the transition metal on the substrate reacts with chalcogen to synthesize transition metal dichalcogenide. Quality of crystals of the transition metal dichalcogenide synthesized by this method is worse.

Another technique uses a chemical vapor deposition (CVD) method or an aqueous solution reaction method to synthesize transition metal dichalcogenide. High-quality two-dimensional crystal materials are typically formed by using the chemical vapor deposition method. In the chemical vapor deposition method, vaporized reactants are firstly formed within a tube furnace, the vaporized reactants nucleate on a substrate, and two-dimensional crystals are formed by epitaxially growing from nucleation sites. Thus, sizes of the two-dimensional crystals formed by using the chemical vapor deposition method are closely associated to a nucleation density and uniformity. However, the nucleation density of the vaporized reactants is difficult to control. For graphene, hexagon or square crystals in millimeters can be grown by using the chemical vapor deposition method. However, for two-dimensional crystals of the transition metal dichalcogenide series materials, a nucleation density is small, such that the two-dimensional crystals formed by using the chemical vapor deposition method are triangular crystals which are grown to have sizes up to 100 micrometer order. Therefore, the transition metal dichalcogenide formed by using the chemical vapor deposition method cannot be applied to a large-area device.

Still another technique uses a bulk exfoliating and transferring method to manufacture transition metal dichalcogenide. However, quality and size of two-dimensional crystals of the transition metal dichalcogenide are difficult to control by using the method.

### SUMMARY

Therefore, one object of the present invention is to provide a method for manufacturing a two-dimensional material, in which there is no electric field generated between a target and a substrate, such that transition metal atoms brought down from the target by the energy beam do not bombard the substrate, thereby keeping the two-dimensional material on the substrate integrated, flat, and uniform.

Another object of the present invention is to provide a method for manufacturing a two-dimensional material, which can grow a large-area two-dimensional material having good-quality crystals, such that the two-dimensional material is easily analyzed and detected, and may be applied to manufacture a large-area device.

According to the aforementioned objectives, the present invention provides a method for manufacturing a two-dimensional material. In this method, an energy beam sputtering process is performed to form a transition metal film on a substrate by using a target. When the energy beam sputtering process is performed, a potential difference between the target and the substrate is 0, such that no electric field is generated between the target and the substrate. A synthesis reaction is performed on the transition metal film within a tube furnace to synthesize a two-dimensional material layer from the transition metal film and chalcogen.

According to one embodiment of the present invention, performing the energy beam sputtering process includes using an energy beam, and the energy beam is an atomic beam, an ion beam, or a light beam.

According to one embodiment of the present invention, the target and the substrate are opposite to each other, and performing the energy beam sputtering process includes projecting an energy beam toward the target.

According to one embodiment of the present invention, a thickness of the transition metal film is ranging from about 0.1 nm to about 2 nm.

According to one embodiment of the present invention, the target and the substrate are not in electrical connection.

According to one embodiment of the present invention, performing the synthesis reaction includes controlling a temperature within the tube furnace at a range from about 700 degrees centigrade to about 1000 degrees centigrade.

According to one embodiment of the present invention, the two-dimensional material layer includes one atomic layer to ten atomic layers.

According to one embodiment of the present invention, the two-dimensional material layer is a transition metal dichalcogenide layer.

According to one embodiment of the present invention, the transition metal film includes Mo, W, Ta, Pt, V, or Nb.

According to one embodiment of the present invention, the chalcogen includes S, Se, or Te.

### BRIEF DESCRIPTION OF THE DRAWINGS

The invention can be more fully understood by reading the following detailed description of the embodiment, with reference made to the accompanying drawings as follows:

FIG. 1A and FIG. 1B are schematic diagrams of installations for manufacturing a two-dimensional material in accordance with one embodiment of the present invention;

FIG. 2 is a flow chart of a method for manufacturing a two-dimensional material in accordance with one embodiment of the present invention;

FIG. 3 is an X-Ray diffraction (XRD) spectrum of a molybdenum disulfide two-dimensional material in accordance with one embodiment of the present invention; and

FIG. 4 illustrates photoluminescence (PL) spectra of a molybdenum disulfide two-dimensional material having seven atomic layers and a molybdenum disulfide two-dimensional material having three atomic layers in accordance with one embodiment of the present invention.

### DETAILED DESCRIPTION

The inventor discovered that because a very large direct current or alternating current electric field exists between a target and a substrate during a magnetron sputtering deposition process, the substrate is bombarded by plasma or even is re-sputtered due to the electric field. For a thick material having dozens of atomic layers, a ratio of a surface to a volume of the thick material is small, such that the situation does not bring about a process problem. However, the two-dimensional material is thin, and plasma bombarding or re-sputtering breaks the two-dimensional material so as to seriously damage flatness and uniformity of the two-dimensional material. In addition, the conventional technique for manufacturing a two-dimensional material cannot form a large-area and good-quality two-dimensional material. In view of the aforementioned reasons, embodiments of the present disclosure provide a method for manufacturing a two-dimensional material, which can manufacture a large-area and high-quality two-dimensional crystal material, particularly a transition metal dichalcogenide series material, thereby greatly expanding application of the two-dimensional material.

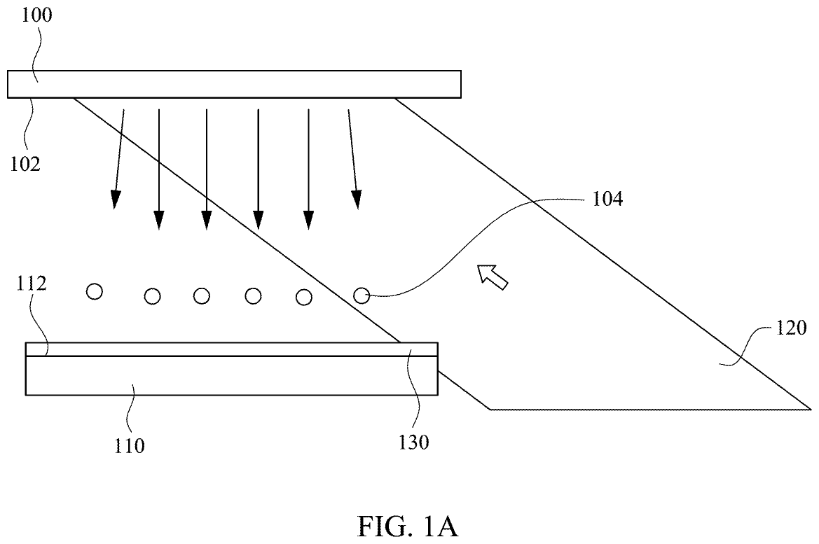

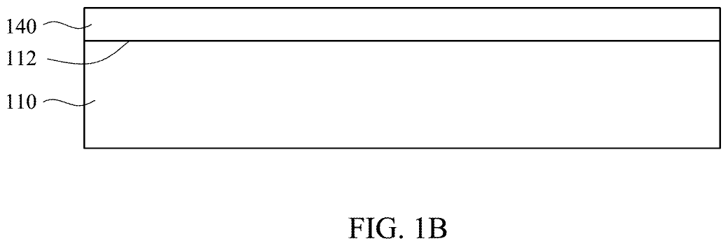

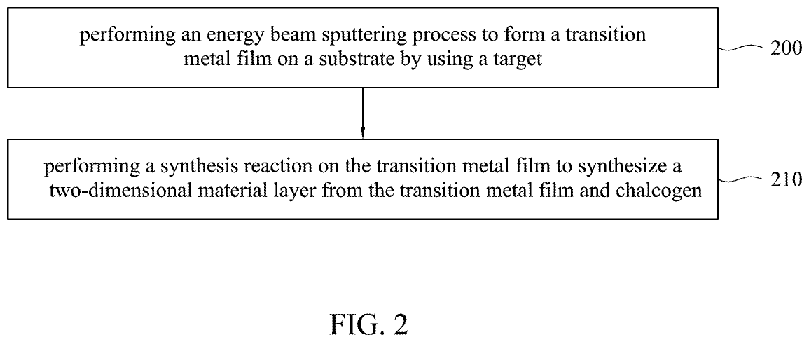

Referring to FIG. 1A, FIG. 1B, and FIG. 2 simultaneously, FIG. 1A and FIG. 1B are schematic diagrams of installations for manufacturing a two-dimensional material in accordance with one embodiment of the present invention, and FIG. 2 is a flow chart of a method for manufacturing a two-dimensional material in accordance with one embodiment of the present invention. In some embodiments, a two-dimensional material is formed by using an energy beam sputtering method, so a target 100 including composition of a two-dimensional material is firstly provided. In the present embodiment, the target 100 includes transition metal. Then, the target 100 and a substrate 110 where the two-dimensional material is formed are disposed opposite to each other, i.e. a surface 102 of the target 100 faces a surface 112 of the substrate 110, as shown in FIG. 1A.

An energy beam 120 may be projected toward the surface 102 of the target 100, such that energy of the energy beam 120 is used to excite the target 100, so as to knock out target atoms 104, and thus the target atoms 104 are deposited on the surface 112 of the substrate 110. Therefore, the energy beam 120 has energy which is sufficient to knock out the target atoms 104. An apparatus generating the energy beam 120 may be adjacent to the target 100 and the substrate 110, or may be far away the target 100 at a distance. The apparatus generating the energy beam 120 may be disposed at which the energy beam 120 generated by the apparatus can be projected onto the surface 102 of the target 100. In some examples, the energy beam 120 may be an atomic beam, an ion beam, or a light beam. The light beam may be, for example, a laser light beam.

As shown in FIG. 2, in manufacturing of a two-dimensional material, a step 200 is firstly performed to perform an energy beam sputtering process using the target 100, so as to project the energy beam 120 onto the surface 102 of the target 100. The energy of the energy beam 120 is used to excite and knock out the target atoms 104 from the target 100. The target atoms 104 knocked out by the energy beam 120 fall down and are deposited on the surface 112 of the substrate 110 to form a transition metal film 130 on the surface 112 of the substrate 110. In some examples, a thickness of the transition metal film 130 may be ranging from about 0.1 nm to about 2 nm. The transition metal film 130 may include one metal element of a transition metal series in the chemical periodic table. For example, the transition metal film 130 may include Mo, W, Ta, Pt, V, or Nb.

In the present embodiment, when the energy beam sputtering process is performed, no electric field is generated between the target 100 and the substrate 110, i.e. a potential difference between the target 100 and the substrate 110 is 0. In some exemplary examples, the target 100 and the substrate 110 are not in electrical connection, i.e. the target 100 and the substrate 110 are not connected to any power supply. In certain examples, the target 100 and the substrate 110 may be in electrical connection, but a potential difference between the target 100 and the substrate 110 is 0.

No electric field is generated between the target 100 and the substrate 110 in the energy beam sputtering process, such that the target atoms 104 knocked out from the target 100 by the energy beam 120 can softly land on the surface 112 of the substrate 110 without bombarding the surface 112 of the substrate 110. Thus, the transition metal film 130 deposited on the surface 112 of the substrate 110 is kept in good flatness and uniformity.

After the energy beam sputtering process is completed, a step 210 may be performed to perform a synthesis reaction on the transition metal film 130 on the substrate 110, so as to synthesize a two-dimensional material layer 140 from the transition metal film 130 and chalcogen, as shown in FIG. 1B. The chalcogen may be any element of oxygen family elements in the chemical periodic table except oxygen. For example, the chalcogen may include S, Se, or Te. In some examples, when the synthesis reaction is performed on the transition metal film 130, the substrate 110 and the transition metal film 130 formed thereon are firstly put into a tube furnace, the chalcogen is then introduced into the tube furnace, and a temperature within the tube furnace is simultaneously increased, such that the transition metal in the transition metal film 130 reacts with the chalcogen to synthesize the two-dimensional material layer 140. In some exemplary examples, performing the synthesis reaction of the transition metal and the chalcogen includes controlling the temperature within the tube furnace at a range from about 700 degrees centigrade to about 1000 degrees centigrade.

In the present embodiment, because the two-dimensional material layer 140 is synthesized from the transition metal and the chalcogen, the two-dimensional material layer 140 is a transition metal dichalcogenide layer. For example, a material of the two-dimensional material layer 140 may be a material having a chemical formula MX₂, in which M in the chemical formula may be a transition metal element, such as Mo, W, Ta, Pt, V, or Nb, and X in the chemical formula may be a chalcogen element, such as S, Se, or Te. In addition, according to application requirements, the two-dimensional material layer 140 may include one atomic layer to ten atomic layers.

Before the synthesis reaction is performed, the transition metal film 130 on the substrate 110 has good flatness and uniformity, such that the two-dimensional material layer 140 formed by synthesizing the transition metal film 130 and the chalcogen also has good flatness and uniformity, and the two-dimensional material layer 140 further has good-quality crystals. In addition, because the flatness and the uniformity of the transition metal film 130 are good, a large-area two-dimensional material layer 140 can be successfully manufactured. For example, an area of the two-dimensional material layer 140 may be equal to or more than two-inch wafer. Furthermore, the energy beam sputtering process of the present embodiment can be integrated with other industry processes, and thus can be applied to mass production.

In one exemplary example, a molybdenum disulfide two-dimensional material is manufactured for example. In this example, an energy beam sputtering process is firstly performed to project a molybdenum target by using an energy beam to eject molybdenum atoms, such that a large-area, flat, and uniform molybdenum film is formed on a surface of a substrate. Then, the substrate and the molybdenum film formed thereon, and sulphur powder are put into a tube furnace, in which a temperature within the tube furnace is controlled at a range from about 800 degrees centigrade to about 950 degrees centigrade. The molybdenum film and the sulphur powder are vulcanized within the tube furnace for about 20 minutes to about 60 minutes, and then a large-area, flat, uniform, and high-quality molybdenum disulfide two-dimensional material is obtained. The molybdenum disulfide two-dimensional material may include one to ten atomic layers.

The molybdenum disulfide two-dimensional material has a large area, such that it is convenient for analysis and detection. Some analyses and detection of the molybdenum disulfide two-dimensional material are made below. An angle resolved photoemission spectroscopy (ARPES) of the molybdenum disulfide two-dimensional material shows that the molybdenum disulfide two-dimensional material has a quality property similar to a single crystal bulk. Such a quality cannot be achieved by using a chemical vapor deposition technique or a magnetron sputtering technique.

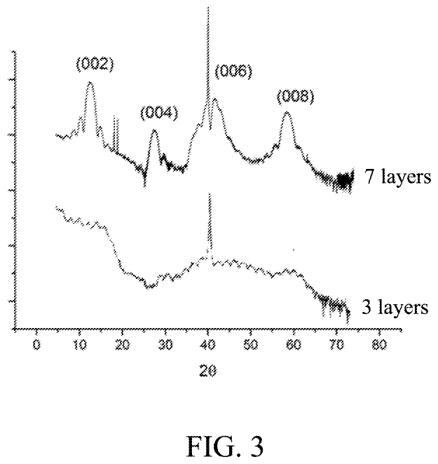

Referring to FIG. 3, FIG. 3 is an X-Ray diffraction spectrum of a molybdenum disulfide two-dimensional material in accordance with one embodiment of the present invention. It can be seen from FIG. 3 that an X-Ray diffraction spectrum of the molybdenum disulfide two-dimensional material shows the molybdenum disulfide two-dimensional material has a quality similar to the single crystal bulk, a large-area, and a uniform property. Such quality and property cannot be achieved by using a chemical vapor deposition technique or a magnetron sputtering technique. A constructive interference of the molybdenum disulfide two-dimensional material having three atomic layers is weaker, so intensity is unobvious, but a main (broader) diffraction peak still can be seen from the X-Ray diffraction spectrum in FIG. 3.

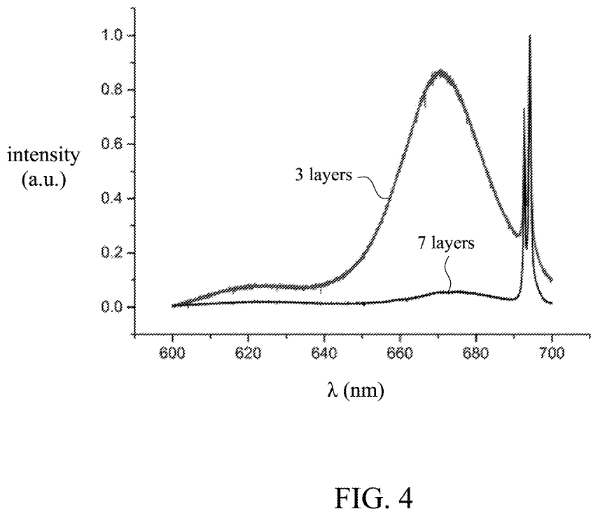

Referring FIG. 4, FIG. 4 illustrates photoluminescence spectra of a molybdenum disulfide two-dimensional material having seven atomic layers and a molybdenum disulfide two-dimensional material having three atomic layers in accordance with one embodiment of the present invention. Photoluminescence spectra of molybdenum disulfide two-dimensional material having seven atomic layers and three atomic layers show that when a quantity of atomic layers of the molybdenum disulfide two-dimensional material is decreased to be close to one, the property of the two-dimensional material (e.g., the direct energy gap property) is shown, and this cannot be achieved by using a chemical vapor deposition technique or a magnetron sputtering technique.

According to the aforementioned embodiments, one advantage of the present invention is that when a two-dimensional material is manufactured by using embodiments of the present invention, there is no electric field generated between a target and a substrate, such that transition metal atoms brought down from the target by the energy beam do not bombard the substrate, thereby keeping the two-dimensional material on the substrate integrated, flat, and uniform.

According to the aforementioned embodiments, another advantage of the present invention is that a method for manufacturing a two-dimensional material of embodiments of the present invention can grow a large-area two-dimensional material having good-quality crystals, such that the two-dimensional material is easily analyzed and detected, and may be applied to manufacture a large-area device.

Although the present invention has been described in considerable detail with reference to certain embodiments thereof, the foregoing embodiments of the present invention are illustrative of the present invention rather than limiting of the present invention. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A method for manufacturing a two-dimensional material, comprising:
performing an energy beam sputtering process to form a transition metal film on a substrate by using a target, wherein when the energy beam sputtering process is performed, a potential difference between the target and the substrate is 0, such that no electric field is generated between the target and the substrate; and
performing a synthesis reaction on the transition metal film within a tube furnace to synthesize a two-dimensional material layer from the transition metal film and chalcogen.

2. The method of claim 1, wherein performing the energy beam sputtering process comprises using an energy beam, and the energy beam is an atomic beam, an ion beam, or a light beam.

3. The method of claim 1, wherein the target and the substrate are opposite to each other, and performing the energy beam sputtering process comprises projecting an energy beam toward the target.

4. The method of claim 1, wherein a thickness of the transition metal film is ranging from 0.1 nm to 2 nm.

5. The method of claim 1, wherein the target and the substrate are not in electrical connection.

6. The method of claim 1, wherein performing the synthesis reaction comprises controlling a temperature within the tube furnace at a range from 700 degrees centigrade to 1000 degrees centigrade.

7. The method of claim 1, wherein the two-dimensional material layer comprises one atomic layer to ten atomic layers.

8. The method of claim 1, wherein the two-dimensional material layer is a transition metal dichalcogenide layer.

9. The method of claim 1, wherein the transition metal film comprises Mo, W, Ta, Pt, V, or Nb.

10. The method of claim 1, wherein the chalcogen comprises S, Se, or Te.
